(19) United States
(12) Patent Application Publication
(10) Pub. No.: US 2009/0107540 A1
(43) Pub. Date: Apr. 30, 2009

(54) Non-Imaging Concentrator With Spacing Nubs

(75) Inventor: Michael Milbourne, El Granada, CA (US)

Correspondence Address: THE MUELLER LAW OFFICE, P.C., 12951 Harwick Lane, San Diego, CA, 92130, US

(73) Assignee: SolFocus, Inc., Mountain View, CA (US)

(21) Appl. No.: 11/927,817

(22) Filed: Oct. 30, 2007

(51) Int. Cl. H01L 31/042; B29C 65/00

(52) U.S. Cl. 136/246; 156/60

(57) ABSTRACT

The present invention is a solar energy system which includes an optical assembly and a non-imaging concentrator. The optical assembly includes a primary mirror and a secondary mirror. The optical assembly reflects solar radiation to the non-imaging concentrator where the radiation is output to a photovoltaic cell for conversion to electricity. Spacing nubs, or protrusions, may be configured on one or more surfaces of the non-imaging concentrator or the optical assembly to set a uniform gap for adhesive to fill and to assist in alignment of the components being bonded together.

### RELATED APPLICATIONS

This application claims priority to U.S. Non-Provisional patent application Ser. No. 11/640,052 filed on Dec. 15, 2006 entitled “Optic Spacing Nubs,” which is hereby incorporated by reference as if set forth in full in this application for all purposes.

### BACKGROUND OF THE INVENTION

It is generally appreciated that one of the many known technologies for generating electrical power involves the harvesting of solar radiation and its conversion into direct current (DC) electricity. Solar power generation has already proven to be a very effective and “environmentally friendly” energy option, and further advances related to this technology continue to increase the appeal of such power generation systems. In addition to achieving a design that is efficient in both performance and size, it is also desirable to provide solar power units that are characterized by reduced cost and increased levels of mechanical robustness.

Solar concentrators are solar energy generators which increase the efficiency of conversion of solar energy to DC electricity. Solar concentrators which are known in the art utilize, for example, parabolic mirrors and Fresnel lenses for focusing the incoming solar energy, and heliostats for tracking the sun's movements in order to maximize light exposure. A new type of solar concentrator, disclosed in U.S. Patent Publication No. 2006/0266408, entitled “Concentrator Solar Photovoltaic Array with Compact Tailored Imaging Power Units” utilizes a front panel for allowing solar energy to enter the assembly, with a primary mirror and a secondary mirror to reflect and focus solar energy through an optical receiver onto a solar cell. The surface area of the solar cell in such a system is, much smaller than what is required for non-concentrating systems, for example less than 1% of the entry window surface area. Such a system has a high efficiency in converting solar energy to electricity due to the focused intensity of sunlight, and also reduces cost due to the decreased surface area of costly photovoltaic cells. Because the receiving area of the solar cell is so small relative to that of the power unit, the ability of the optical components to accurately focus the sun's rays onto the solar cell is important to achieving the desired efficiency of such a solar concentrating system.

A similar type of solar concentrator is disclosed in U.S. Patent Publication No. 2006/0207650, entitled “Multi-Junction Solar Cells with an Aplanatic Imaging System and Coupled Non-Imaging Light Concentrator.” The solar concentrator design disclosed in this application uses a solid optic, out of which a primary mirror is formed oil its bottom surface and a secondary mirror is formed in its upper surface. Solar radiation enters the upper surface of the solid optic, reflects from the primary mirror surface to the secondary mirror surface, and then enters a non-imaging concentrator which outputs the light onto a photovoltaic solar cell.

In these types of solar concentrators, one of the factors in optical component alignment is the process by which the optical receiver or non-imaging concentrator is adhered within the solar energy unit. Uncontrolled adhesive application may result in variations in adhesive thickness across the bonding surfaces of the optical receiver, which in turn may affect the alignment of the optical components as well as affecting the bond strength which is important for withstanding high temperature conditions in a solar power assembly. In another manufacturing scenario, a proper amount of adhesive may be applied, but the optical components may be pressed together in an uncontrolled manner causing adhesive to be exuded beyond the desired bond area and into spaces where an air gap is required for its optical index. Difficulty in attaining consistent adhesive application can decrease manufacturability and consequently the commercial feasibility of such a design.

One solution to this problem of component alignment and attachment is using spacers to set the distance between a component and the substrate to which it is to be bonded. U.S. Pat. No. 5,433,911 entitled “Precisely Aligning and Bonding a Glass Cover Plate Over an Image Sensor” discloses an electronics package which includes a spacer plate, a glass cover plate, an image sensor, and a carrier. In order to achieve the tight tolerances for spacing and parallelism which are required to align the various planar components in this assembly, precision ground and lapped spacers are placed between the components. Spacer particles are another approach to setting uniform distances between surfaces. U.S. Pat. No. 7,102,602 entitled “Doubly Curved Optical Device for Eyewear and Method for Making the Same” discloses a pair of substrates sealed together by a fluid material with spacers disbursed therein. The substrates thus have a uniform controlled distance therebetween due to the presence of the spacers. The spacers may be placed between the substrates prior to application of the fluid, or they may be mixed into the fluid material first and then applied to the unopposed substrates.

While the spacers described above offer possible manufacturing options, it is desirable to facilitate reliable alignment and attachment of the optical components in a solar energy system in a manner which further enhances manufacturability, reduces overall cost, and improves mechanical robustness.

### SUMMARY OF THE INVENTION

The present invention is a solar energy system which includes an optical assembly and a non-imaging concentrator. The optical assembly includes a primary mirror and a secondary mirror, and reflects solar radiation to the non-imaging concentrator. Solar radiation is output from the non-imaging concentrator to a photovoltaic cell for conversion to electricity. An upper surface of the non-imaging concentrator is adhered to the optical assembly, while a lower surface of the non-imaging concentrator is adhered to the photovoltaic cell. Spacing nubs, or protrusions, are configured on one or more adhesive substrates to set a uniform gap for adhesive to fill and to assist in alignment of the components being bonded together. In one embodiment, the nubs are integral to a substrate, such as rounded nubs being formed on the upper surface of the non-imaging concentrator. In another embodiment, indentations may be formed in the surface mating with the nubs to further align optical components. The nubs improve the attachment and alignment of the non-imaging concentrator in the solar energy system, thereby reducing the manufacturing cost and improving the mechanical robustness of the solar energy system.

### BRIEF DESCRIPTION OF THE DRAWINGS

FIG. 1 is a cross-sectional view of an exemplary solar energy system;

FIG. 2 provides a cross-sectional view of the non-imaging concentrator from FIG. 1;

FIGS. 3A, 3B, 3C, and 3D illustrate embodiments of spacing nubs on the non-imaging concentrator of FIG. 2;

FIGS. 4A, 4B, 4C, and 4D are perspective views of exemplary embodiments of non-imaging concentrators;

FIG. 5 is a cross-sectional view of second type of solar energy system; and

FIG. 6 is a flowchart of an exemplary assembly process for adhering optical components together.

### DETAILED DESCRIPTION OF THE EMBODIMENTS

Reference now will be made in detail to embodiments of the disclosed invention, one or more examples of which are illustrated in the accompanying drawings.

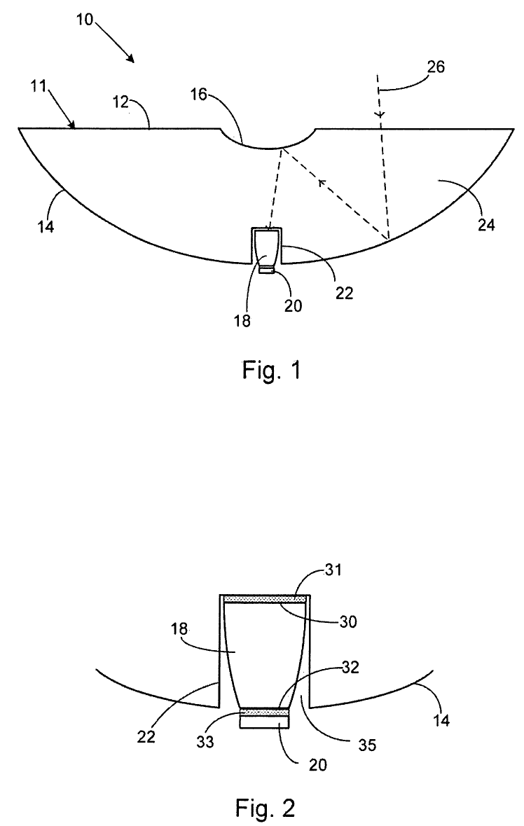

FIG. 1 shows a cross-sectional view of an exemplary solar energy unit 10 as described in U.S. Patent Publication No. 2006/0207650, entitled “Multi-Junction Solar Cells with an Aplanatic Imaging System and Coupled Non-Imaging Light Concentrator.” The solar energy unit 10 includes an optical assembly 11, a non-imaging concentrator 18, and a photovoltaic cell 20. Optical assembly 11 includes an entrance aperture 12, a primary mirror 14, and a secondary mirror 16 which is co-planar with entrance aperture 12 of primary mirror 14. The non-imaging concentrator 18 is positioned at a recessed area 22 located substantially at the vertex of the primary mirror 14, such that non-imaging concentrator 18 channels light which has been reflected from primary mirror 14 and secondary mirror 16 to the photovoltaic solar cell 20. A dielectric 24 chosen with a suitable index of refraction “n,” such as a value of “n” being 1.4 to 1.5, may fill the space between the primary mirror 14 and the secondary mirror 16.

Incident solar radiation 26, depicted as dotted lines in FIG. 1, enters the solar energy unit 10 through entrance aperture 12. Solar radiation 26 travels through the dielectric 24, reflects off of primary mirror 14 and secondary mirror 16, and enters the non-imaging concentrator 18 which channels the solar radiation 26 to solar cell 20. For the purposes of this disclosure, non-imaging concentrator 18 may refer to known means for channeling or concentrating light, such its a total internal reflection prism, an optical rod, or parabolic concentrator.

A close-up cross-sectional view of non-imaging concentrator 18 within recessed area 22 is depicted in FIG. 2. In this view, an upper surface 30 of non-imaging concentrator 18 is mounted to recessed area 22 with an optically suitable adhesive 31. Similarly, a lower surface 32 is bonded to solar cell 20 with an optically suitable adhesive 33. The process of assembling these components typically involves dispensing adhesive onto one of the substrates being bonded, and then pressing the components together with enough force to ensure that adequate contact of the adhesive is made. From FIG. 2, it can be understood that alignment of non-imaging concentrator 18 within recessed area 22 and with respect to solar cell 20 is highly dependent upon the assembly process for applying adhesives 31 and 33. For instance, asymmetrical pressure application across the surface of the solar cell 20 may result in lateral as well as angular misalignment of the solar cell 20 with respect to non-imaging concentrator 18. Lateral misalignment of solar cell 20 can cause losses in solar energy due to the solar cell 20 not being directly positioned underneath non-imaging concentrator 18. Angular misalignment, such as the adhesive 33 being thicker oil one end than the other, may result in inadequate bond strength. In other examples of defects related to manufacturing errors, under-compression of parts may result in insufficient surface area being contacted by adhesive, while over-compression of parts during assembly may result in adhesive being exuded into unwanted areas. In a situation where non-imaging concentrator 18 is a total internal reflector, preventing adhesive 31 from exuding past upper surface 30 is important for maintaining a differential optical index provided by an air gap 35 which surrounds the non-imaging concentrator 18.

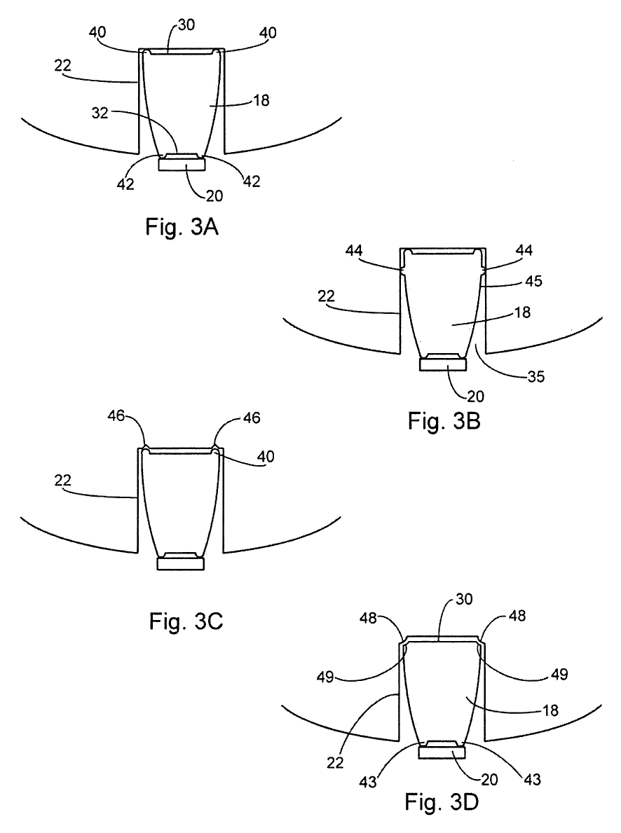

To address these manufacturing issues, FIGS. 3A, 3B, 3C, and 3D depict embodiments of the present invention in which spacing nubs, or protrusions, are used for setting a specific gap distance for adhesive to fill. In FIG. 3A, a plurality of upper nubs 40 and lower nubs 42 have been added to upper surface 30 and lower surface 32, respectively, of non-imaging concentrator 18. In this embodiment, upper nubs 40 and lower nubs 42 are depicted as integrally formed, for example by molding, in non-imaging concentrator 18. Alternatively, upper nubs 40 and lower nubs 42 may be separate components which are insert-molded into non-imaging concentrator 18 or otherwise attached to non-imaging concentrator 18 during its fabrication. The heights of upper nubs 40 are substantially equal to each other, thus advantageously setting a substantially uniform gap between upper surface 30 of non-imaging concentrator 18 and recessed area 22 to which it will be bonded. The tipper nubs 40 may, for instance, have a height between 20 microns to 3.0 millimeters for a non-imaging concentrator having a width of 10 millimeters to 30 millimeters at upper surface 30. Similarly, the heights of lower nubs 42 are substantially equal to each other to set a substantially uniform gap between lower surface 32 and solar cell 20. Because upper nubs 40 and lower nubs 42 determine the adhesive gap, a manufacturing operator may properly set the attachment and alignment of optical components by pushing components together until upper nubs 40 or lower nubs 42 are in contact with their corresponding substrate, rather than by needing to monitor the amount and angle of force applied while pushing components together.

FIG. 3B shows a modified nub arrangement in which side nubs 44 have been added to outer walls 45 of non-imaging concentrator 18. Side nubs 44 may include, for example, three or four side nubs 44 spaced equally around outer walls 45 which form the circumference of non-imaging concentrator 18. Side nubs 44 assist in centering non-imaging concentrator 18 within recessed area 22. Centering may be important for maintaining a differential optical index provided by the air gap 35 surrounding non-imaging concentrator IS, such as when non-imaging concentrator 18 is a total internal reflector. In FIG. 3C, another embodiment of the present invention is shown. Indentations 46 are formed in recessed area 22 to mate with upper nubs 40, consequently substantially centering non-imaging concentrator 18 within recessed area 22. The height of upper nubs 40, subtracting the distance which they are seated into indentations 46, determines the gap height for adhesive to fill.

FIG. 3D shows yet another embodiment of the present invention, in which corner nubs 48 protrude from the recessed area 22 rather than from the non-imaging concentrator 18. In this embodiment of FIG. 3D, the corner nubs 48 mate with dimples 49 formed in the corners of non-imaging concentrator 18. Because corner nubs 48 are formed in the corners of recessed area 22, corner nubs 48 constrain both the vertical and lateral positioning of non-imaging concentrator 18 within recessed area 22. Thus, the adhesive gap height between upper surface 30 and recessed area 22 as well as the centering of non-imaging concentrator 18 within recessed area 22 are both determined by the mating of corner nubs 48 with dimples 49. Note that FIG. 3D also illustrates a further embodiment of lower nubs 43, in which lower nubs 43 are configured with a flat surface mating with solar cell 20, rather than a rounded surface as shown with lower nubs 42 in FIGS. 3A, 3B, and 3C.

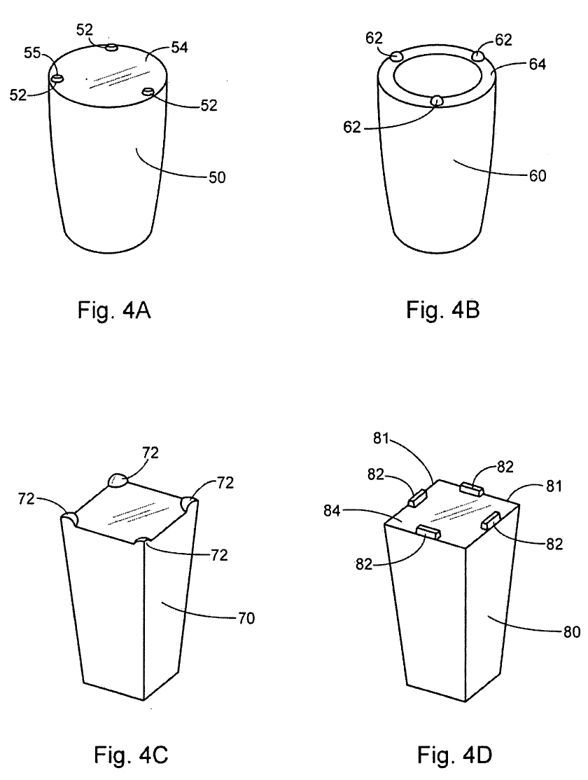

The perspective views of FIGS. 4A, 4B, 4C, and 4D illustrate exemplary configurations of spacing nubs on non-imaging concentrators. Note that for clarity, the nubs in these figures are shown proportionally larger with respect to the non-imaging concentrators than they may be in reality. In FIG. 4A, a non-imaging concentrator 50 is depicted as an optical rod, with three flat nubs 52 located on an upper surface 54 of non-imaging concentrator 50. Flat nubs 52 are shaped as truncated cones spaced approximately evenly around the perimeter of upper surface 54. Note that three is a desirable number for establishing a planar alignment of upper surface 54. However, more than three flat nubs 52 may be utilized, or two may be acceptable if top faces 55 of flat nubs 52 have sufficient surface area for establishing stable planar contact with their mating surface. In FIG. 4B, a non-imaging concentrator 60 takes the form of a hollow concentrator, such as a parabolic concentrator with an inner reflective surface coating. Rounded nubs 62 are located around the circumference of an upper surface 64 of non-imaging concentrator 60. The rounded profiles of rounded nubs 62 may be, for example, hemispherical, elliptical, or other curved profile. The rounded nubs 62 provide a point contact with a mating substrate, which may be desirable for reducing potential errors caused by dimensional defects formed in the top laces 55 of the flat nubs 52 of FIG. 3A.

FIGS. 4C and 4D depict non-imaging concentrators as total internal reflection prisms with yet other embodiments of spacing nubs. A non-imaging concentrator 70 of FIG. 4C shows quarter nubs 72 configured as rounded protrusions at the corners of non-imaging concentrator 70. In FIG. 4D, rectilinear nubs 82 are approximately centered on the edges 81 of a non-imaging concentrator 80, with rectilinear nubs 82 configured with extended nub lengths and polygonal profiles. Rectilinear nubs 82 may have lengths spanning the full lengths of edges 81 to encapsulate an adhesive within upper surface 84 of non-imaging concentrator 80, although leaving some open space along the edges 81 may be desirable for allowing air to escape while adhesive is being spread across the upper surface 84 during the assembly process.

Note that while the non-imaging concentrators 70 and 80 are depicted as square prisms, other shapes are possible such as hexagonal or octagonal prisms. Furthermore, although the nub configurations shown in FIGS. 4A, 4B, 4C, and 4D are illustrated on the upper surfaces of non-imaging concentrators, the same nub configurations may also be applicable to the lower surfaces of a non-imaging concentrator for adhering a solar cell onto the non-imaging concentrator. Additionally, the nub features shown oil the non-imaging concentrators in FIGS. 4A, 4B, 4C, and 4D may instead be incorporated on their mating components, such as the recessed area 22 or on the solar cell 20. Spacing nubs may be present on one or both of the upper and lower surfaces of a non-imaging concentrator.

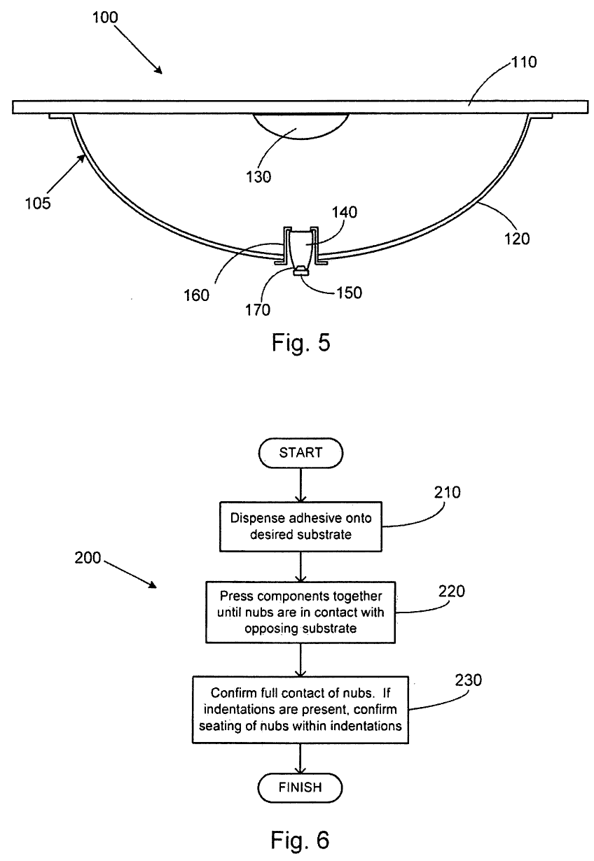

FIG. 5 depicts a solar energy unit 100 including an optical assembly 105 fabricated from separate components rather than being formed from one piece as in FIG. 1. In FIG. 5, a solar energy unit 100 has an optical assembly 105 which includes a panel 110, a radially symmetric primary mirror 120, a radially symmetric secondary mirror 130, and a bracket 160. The planar surface provided by panel 110 is a protective cover for the optical assembly 105, is the surface through which solar radiation enters, and is the surface to which primary mirror 120 and secondary mirror 130 are attached. Primary mirror 120 and secondary mirror 130 reflect incoming solar radiation to a non-imaging concentrator 140, which then directs the radiation to a solar cell 150 for conversion to electricity. The non-imaging concentrator 140 is held in place by a bracket 160, and the solar cell 150 is mounted to the bottom of non-imaging concentrator 140 with adhesive as described with the solar energy unit 10 of FIG. 1. Spacing nubs 170 at the bottom of non-imaging concentrator 140 can help to align and properly adhere the solar cell 150 to non-imaging concentrator 140 in the same way that has been described previously for solar energy unit 10.

FIG. 6 illustrates exemplary steps for assembling optical components involving spacing nubs. In flowchart 200 of FIG. 6, a manufacturing operator first dispenses adhesive onto a desired substrate in step 210. The amount of adhesive may be pre-measured, or may be visually estimated. In step 220, the manufacturing operator presses the desired components together until all the spacing nubs are in contact with the opposing substrate. The process of pressing the components together may involve rotation of the components to distribute the adhesive, so that the adhesive provides complete optical coupling between the surfaces. Confirmation that the nubs are in contact the opposing substrate, and therefore that the adhesive gap is uniform across the substrates, is performed in step 230. If indentations are present to provide further alignment between components, confirmation that the nubs are properly seated in the indentations is also performed in step 230. The confirmations performed in step 230 may involve processes such as a visual check or applying additional pressure to the components.

Although embodiments of the invention have been discussed primarily with respect to specific embodiments thereof, other variations are possible. Lenses or other optical devices might be used in place of, or in addition to, the primary and secondary mirrors or other components presented herein. For example, a Fresnel lens could be used to focus light onto the optical assembly, or to focus light at an intermediary phase after processing by the optical assembly. Other embodiments can use optical or other components for focusing any type of electromagnetic energy such as infrared, ultraviolet, or radio-frequency. There may be other applications for the fabrication method and apparatus disclosed herein, such as in the fields of light emission or sourcing technology (e.g., fluorescent lighting using a trough design, incandescent, halogen, spotlight, etc.) where a light source is put in the position of the photovoltaic cell. In general, any type of suitable cell, such as a photovoltaic cell, concentrator cell or solar cell can be used. In other applications it may be possible to use other energy such as any source of photons, electrons or other dispersed energy that can be concentrated. Note that steps can be added to, taken from or modified from the steps in this specification without deviating from the scope of the invention. In general, any flowcharts presented are only intended to indicate one possible sequence of basic operations to achieve a function, and many variations are possible.

While the specification has been described in detail with respect to specific embodiments of the invention, it will be appreciated that those skilled in the all, upon attaining an understanding of the foregoing, may readily conceive of alterations to, variations of, and equivalents to these embodiments. These and other modifications and variations to the present invention may be practiced by those of ordinary skill in the art, without departing from the spirit and scope of the present invention, which is more particularly set forth in the appended claims. Furthermore, those of ordinary skill in the art will appreciate that the foregoing description is by way of example only, and is not intended to limit the invention. Thus, it is intended that the present subject matter covers such modifications and variations as come within the scope of the appended claims and their equivalents.

What is claimed is:

1. A solar energy system, comprising:
an optical assembly;
a non-imaging concentrator to collect light from said optical assembly, wherein said non-imaging concentrator has a mounting surface for being mounted to said optical assembly;
a solar cell receiving light from said non-imaging concentrator, said solar cell creating an electrical output;
a plurality of nubs with nub heights on said mounting surface of said non-imaging concentrator; and
an adhesive substance, wherein said non-imaging concentrator is secured to said optical assembly by said adhesive substance, and wherein said nub heights provide a substantially uniform gap between said optical assembly and said mounting surface of said non-imaging concentrator.

2. The solar energy system of claim 1, wherein said nub heights determine the bond thickness of said adhesive substance.

3. The solar energy system of claim 1, wherein said nubs heights are substantially equal, and wherein said nubs are configured on said perimeter of said mounting surface of said non-imaging concentrator.

4. The solar energy system of claim 1, wherein said nubs are integral to said mounting surface of said non-imaging concentrator.

5. The solar energy system of claim 1, wherein said optical assembly comprises a primary mirror and a secondary mirror, and wherein the space between said primary mirror and said secondary mirror includes a dielectric.

6. The solar energy system of claim 1, wherein said non-imaging concentrator provides total internal reflection.

7. The solar energy system of claim 6, wherein said non-imaging concentrator is a prism.

8. The solar energy system of claim 1, wherein said non-imaging concentrator is a light tunnel.

9. The solar energy system of claim 1, wherein said non-imaging concentrator comprises a refractive lens.

10. The solar energy system of claim 1, wherein said non-imaging concentrator further comprises a bottom surface, said bottom surface comprising a second set of nubs, wherein said second set of nubs provides a substantially uniform gap between said bottom surface of said non-imaging concentrator and said solar cell.

11. The solar energy system of claim 1, wherein said non-imaging concentrator further comprises outer walls with a lateral set of nubs located on said outer walls, and wherein said lateral set of nubs sets a gap between said non-imaging concentrator and said optical assembly.

12. The solar energy system of claim 1, wherein said optical assembly further comprises indentations for mating with said plurality of nubs, and wherein said mating of said indentations with said plurality of nubs aligns said non-imaging concentrator with said optical assembly.

13. A solar energy system, comprising:
a substantially planar surface;
a primary mirror radially symmetric about a first axis, said primary mirror having a perimeter wherein at least a portion of said perimeter is attached to said planar surface;
a secondary mirror radially symmetric about a second axis, said secondary mirror having a mounting surface wherein at least a portion of said mounting surface is attached to said planar surface;
a non-imaging concentrator positioned to receive light reflected from said primary mirror and from said secondary mirror, said non-imaging concentrator having a bottom surface;
a solar cell receiving light from said non-imaging concentrator, said solar cell creating an electrical output;
a plurality of nubs on said bottom surface of said non-imaging concentrator, said nubs having nub heights, wherein said nub heights are substantially equal; and
an adhesive substance, wherein said solar cell is secured to said non-imaging concentrator by said adhesive substance, and wherein said nubs provide a substantially uniform gap between said solar cell and said non-imaging concentrator for said adhesive substance.

14. The solar energy system of claim 13, wherein said plurality of nubs are integral to said non-imaging concentrator.

15. The solar energy system of claim 13, wherein said non-imaging concentrator is a total internal reflection prism.

16. The solar energy system of claim 13, wherein said non-imaging concentrator is an optical rod.

17. A method of attaching and aligning a non-imaging concentrator with integral nubs to a mating component in a solar energy system, comprising:
dispensing an adhesive onto said non-imaging concentrator;
positioning said non-imaging concentrator with said integral nubs with respect to said mating components;
applying pressure to said non-imaging concentrator and to said mating component until said nubs are in contact with said mating component; and
confirming contact of said nubs with said mating component;
wherein said integral nubs have nub heights, and wherein said nub heights provide a substantially uniform gap in which to distribute said adhesive substance.

18. The method of claim 17, wherein said mating component is a solar cell.

19. The method of claim 17, wherein said mating component is a recessed area within an aplanatic optical imaging system.

20. The method of claim 19, wherein said non-imaging concentrator further comprises a second set of nubs on an outer surface of said non-imaging concentrator, wherein said second set of nubs centers said non-imaging concentrator within said recessed area.
